(19) United States
(12) Patent Application Publication
(10) Pub. No.: US 2025/0107289 A1
(43) Pub. Date: Mar. 27, 2025

(54) DISPLAY DEVICE AND METHOD OF MANUFACTURING THE SAME

(71) Applicant: Samsung Display Co., LTD., Yongin-si (KR)

(72) Inventors: SEON UK LEE, Yongin-si (KR); KWANG-MIN LEE, Yongin-si (KR); JUNHWI LIM, Yongin-si (KR)

(21) Appl. No.: 18/768,461

(22) Filed: Jul. 10, 2024

(30) Foreign Application Priority Data
Sep. 25, 2023 (KR) 10-2023-0127753

(51) Int. Cl. H01L 33/50; H01L 33/00; H01L 33/06; H10K 59/12; H10K 59/38

(52) U.S. Cl. CPC H10H 20/8514; H10H 20/01; H10H 20/812; H10K 59/1201; H10K 59/38; H10H 20/0361

(57) ABSTRACT

A display device includes a light control layer including a plurality of light control patterns and a division pattern that divides the plurality of light control patterns. The division pattern includes a plurality of side walls that define the openings. The plurality of side walls includes first side walls and second side walls. The first side walls include a first inclined surface inclined in a direction away from a corresponding light control pattern among the plurality of light control patterns.

This application claims priority to Korean Patent Application No. 10-2023-0127753, filed on Sep. 25, 2023, and all the benefits accruing therefrom under 35 U.S.C. § 119, the content of which in its entirety is herein incorporated by reference.

### BACKGROUND

### 1. Field

Embodiments of the disclosure described herein relate to a display device, and more particularly, relate to a display device having relatively high resolution.

### 2. Description of the Related Art

Various display devices used in multimedia devices such as televisions, mobile phones, tablet computers, and game consoles are being developed. The display device may include various optical functional layers for providing a color image having excellent quality to a user.

Research on thin display devices is being conducted to implement various types of display devices such as display devices including curved surfaces, rollable display devices, or foldable display devices. The thin display device may be implemented by reducing the number of optical functional layers and including the optical functional layers including various functions.

### SUMMARY

Embodiments of the disclosure provide a display device capable of a fine inkjet process.

In an embodiment of the disclosure, a display device includes a display panel including a plurality of light-emitting elements that emit a source light, and a light control layer disposed on the display panel and including a plurality of light control patterns and a division pattern that divides the plurality of light control patterns. A plurality of openings in which the light control patterns are arranged, is defined in the division pattern, and the division pattern includes a plurality of side walls that define the openings. The plurality of side walls includes first side walls extending in a first direction, facing each other with a corresponding light control pattern among the plurality of light control patterns interposed therebetween, and spaced apart from each other by a first distance in a second direction perpendicular to the first direction, and second side walls extending in the second direction and spaced apart from each other by a second distance which is greater than the first distance in the first direction with the corresponding light control pattern interposed therebetween. Each of the first side walls includes a first inclined surface inclined in a direction away from the corresponding light control pattern.

In an embodiment, the first side walls may include a (1-1)^{th} side wall and a (1-2)^{th} side wall facing each other with the corresponding light control pattern interposed therebetween.

In an embodiment, the first inclined surface may include a (1-1)^{th} inclined surface formed on the (1-1)^{th} side wall, and a (1-2)^{th} inclined surface formed on the (1-2)^{th} side wall.

In an embodiment, a first width of the (1-1)^{th} inclined surface in the second direction may be the same as a second width of the (1-2)^{th} inclined surface in the second direction.

In an embodiment, each of the first width and the second width may be in a range of about 3.5 micrometers (μm) or more and about 4.0 μm less.

In an embodiment, the second side walls may include a (2-1)^{th} side wall and a (2-2)^{th} side wall facing each other with the corresponding light control pattern interposed therebetween.

In an embodiment, at least some of the second side walls may include a second inclined surface inclined in the direction away from the corresponding light control pattern, and the second inclined surface may include a (2-1)^{th} inclined surface formed on the (2-1)^{th} side wall, and a (2-2)^{th} inclined surface formed on the (2-2)^{th} side wall.

In an embodiment, each of the first side walls may further include a first side surface extending from the first inclined surface and being in direct contact with the plurality of light control patterns.

In an embodiment, each of the plurality of openings may include a first sub-opening defined by the first inclined surface, and a second sub-opening defined by the first side surface.

In an embodiment, a width of the first sub-opening in the second direction may gradually decrease toward the second sub-opening.

In an embodiment, a maximum width of the first sub-opening in the second direction may be in a range of about 34.8 μm or more and about 35.8 μm or less.

In an embodiment, a width of the second sub-opening in the second direction may gradually increase as a distance from the first sub-opening increases.

In an embodiment, the light control patterns may include first, second and third light control patterns disposed in the first direction, and the plurality of side walls may further include a non-inclined side wall in contact with the third light control pattern.

In an embodiment, the division pattern may be provided in plural, and a width between two adjacent division patterns among a plurality of division patterns in the second direction may be in a range of about 13 μm or more and about 15 μm or less.

In an embodiment, the first inclined surface may have non-liquid repellent properties.

In an embodiment, a method of manufacturing a display device includes arranging a base member, arranging a preliminary division pattern on the base member, forming, on the preliminary division pattern, first side walls extending in a first direction and spaced apart from each other by a first distance in a second direction perpendicular to the first direction and second side walls extending in the second direction and spaced apart from each other by a second distance which is greater than the first distance in the first direction, forming a first inclined surface by patterning upper portions of the first side walls, providing an ink composition to an opening defined by the first side walls and the second side walls, and forming a light control layer including a light control pattern by curing the ink composition. In the providing the ink composition, the ink composition is provided to overlap the first inclined surface.

In an embodiment, the forming the first inclined surface may be performed simultaneously with the forming the first side walls.

In an embodiment, the first inclined surface may be formed in a direction away from the light control pattern.

In an embodiment, the base member may include a base substrate and a color filter layer disposed on the base substrate, and the preliminary division pattern may be formed on one surface of the color filter layer.

In an embodiment, the method may further include providing a display panel including a display element layer, and assembling the light control layer and the display panel.

### BRIEF DESCRIPTION OF THE DRAWINGS

The above and other embodiments, advantages and features of the disclosure will become apparent by describing in detail embodiments thereof with reference to the accompanying drawings.

FIG. 1 is a perspective view of an embodiment of a display device according to the disclosure.

FIG. 2A is a plan view of an embodiment of a portion of the display device according to the disclosure.

FIG. 2B is a plan view of an embodiment of a portion of the display device according to the disclosure.

FIG. 3A is a cross-sectional view of an embodiment of the display device according to the disclosure.

FIG. 3B is a cross-sectional view of an embodiment of the display device according to the disclosure.

FIG. 4 is a plan view of an embodiment of a light control panel according to the disclosure.

FIG. 5 is a cross-sectional view of an embodiment of a portion of the light control panel according to the disclosure.

FIG. 6 is a cross-sectional view of the light control panel at a portion corresponding to line II-II′ of FIG. 5.

FIG. 7A is an enlarged view of area CC' of FIG. 6.

FIG. 7B is an enlarged view of area DD' of FIG. 6.

FIG. 8 is a cross-sectional view of the light control panel at a portion corresponding to line III-III′ of FIG. 5.

FIG. 9A is a cross-sectional view of an embodiment of the portion of the light control panel according to the disclosure.

FIG. 9B is a cross-sectional view of the light control panel at a portion corresponding to line IV-IV′ of FIG. 9A.

FIGS. 10A to 10E are schematic views illustrating an embodiment of operations of a method of manufacturing a portion of the display device according to the disclosure.

### DETAILED DESCRIPTION

Since the disclosure is variously modified and has alternative forms, an embodiment thereof will be illustrated in the drawings and will be described herein in detail. However, it should be understood that the disclosure is not limited to a predetermined disclosure and includes all changes, equivalents, and substitutes included in the spirit and scope of the disclosure.

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in

the drawings, the thickness, the ratio, and the dimension of components are exaggerated for effective description of technical contents.

The term “and/or” includes all combinations of one or more components that may be defined by associated configurations.

The terms “first”, “second”, etc. are used to describe various components, but the components should not be limited by the terms. The terms are only used to distinguish one component from another component. For example, without departing from the right scope of the disclosure, a first component may be referred to as a second component, and similarly, the second component may be also referred to as the first component. Singular expressions include plural expressions unless clearly otherwise indicated in the context.

Further, the terms “under”, “beneath”, “on”, “above”, etc. are used to describe a relationship between components illustrated in the drawings. The terms have relative concepts and are described with reference to a direction indicated in the drawing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical terms and scientific terms) used in the specification have the same meaning as commonly understood by those skilled in the art to which the disclosure belongs. Further, terms defined should be construed as having the same meanings as those in the context of the related art, and are explicitly defined therein unless the terms are interpreted in an ideal or excessive formal meaning.

It will be understood that the terms “include”, “comprise”, “have”, etc. specify the presence of features, numbers, steps, operations, elements, or components, described in the specification, or any combinations thereof, not precluding the presence or additional possibility of one or more other features, numbers, steps, operations, elements, or components or any combinations thereof.

Hereinafter, an embodiment of the disclosure will be described with reference to the accompanying drawings.

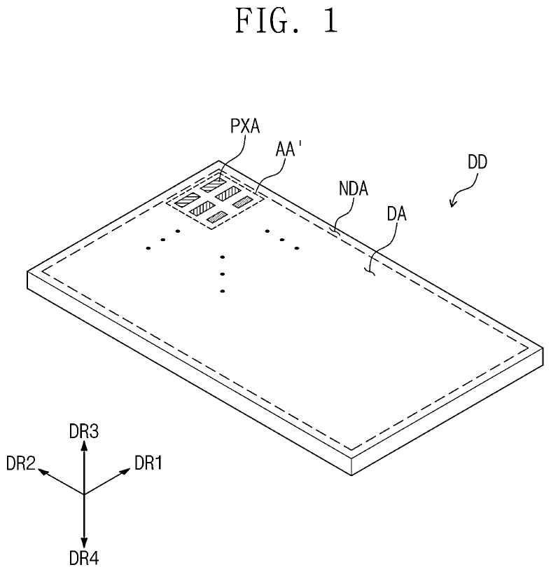

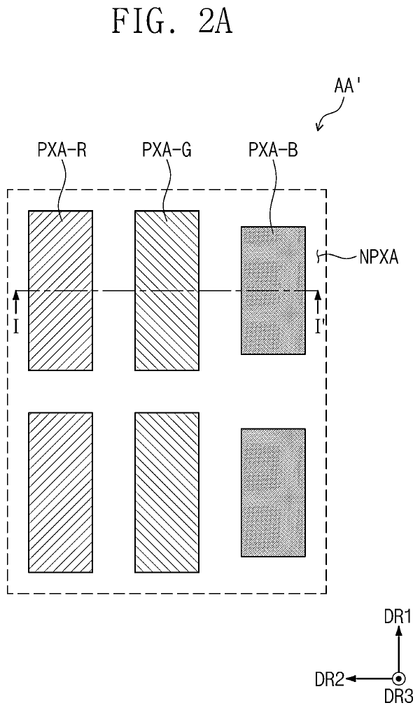

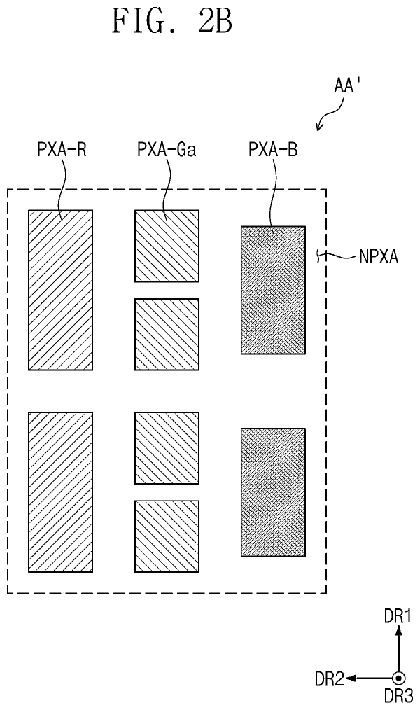

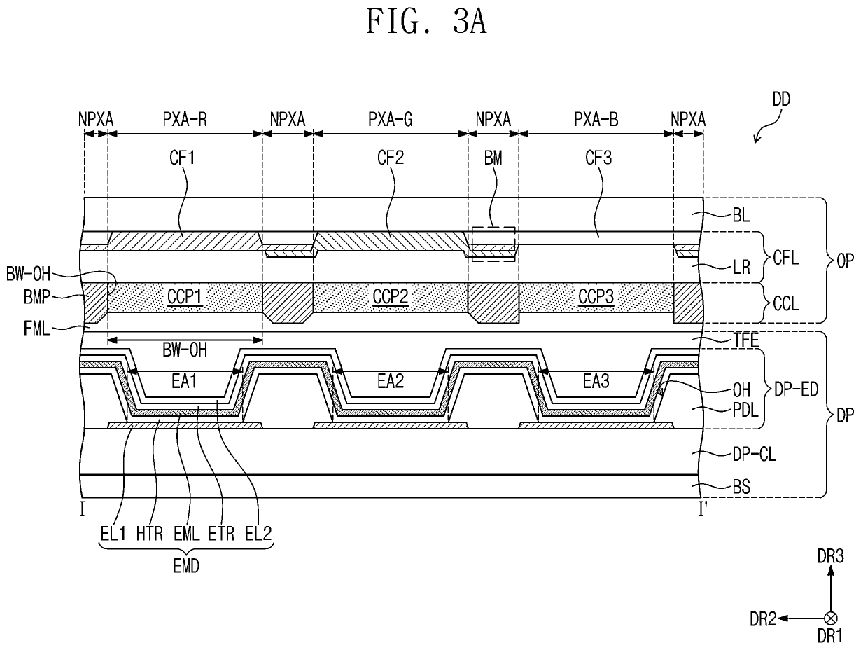

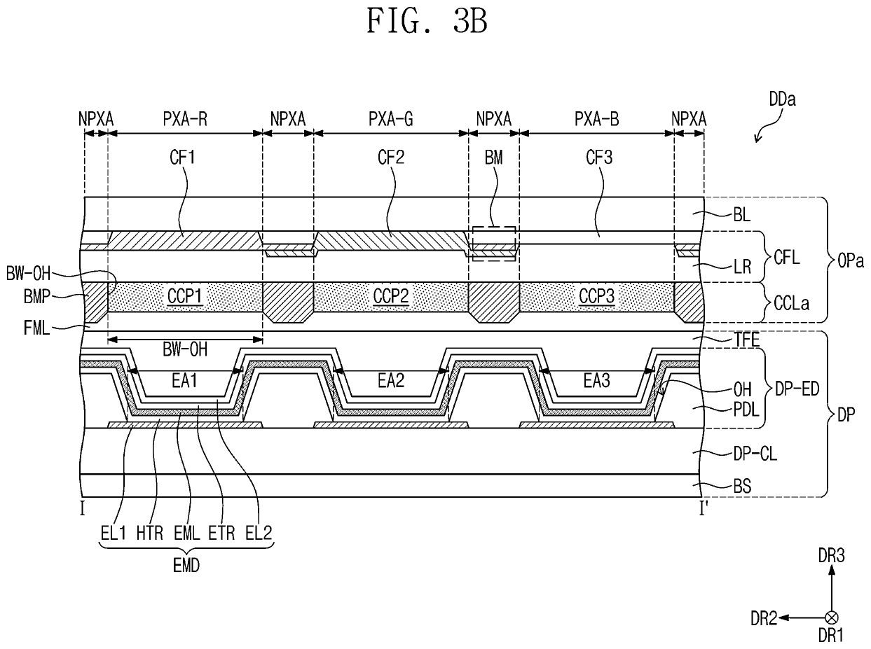

FIG. 1 is a perspective view of an embodiment of a display device according to the disclosure. FIG. 2A is a plan view of an embodiment of a portion of the display device according to the disclosure, and FIG. 2B is a plan view of an embodiment of a portion of the display device according to the disclosure. FIGS. 3A and 3B are cross-sectional views of an embodiment of the display device according to the disclosure. FIGS. 2A and 2B are plan views illustrating a portion corresponding to area AA′ of FIG. 1, and FIGS. 3A and 3B are cross-sectional views corresponding to line I-I′ of FIG. 2A.

A display device DD in an embodiment of the disclosure may be a device that is activated according to an electrical signal. In an embodiment, the display device DD may be a mobile phone, a tablet computer, a vehicle navigation system, a game console, or a wearable device, for example, but the disclosure is not limited thereto.

In FIG. 1 and the following drawings, a first direction DR1 to a fourth direction DR4 are illustrated, and directions indicated by the first, second, third and fourth directions DR1, DR2, DR3, and DR4 described in the specification are relative concepts and may be changed to different directions. Further, directions indicated by the first, second, third and fourth directions DR1, DR2, DR3, and DR4 may be described as first to fourth directions, and the same reference numerals may be used for the same directions.

In the specification, a thickness direction of the display device DD may be parallel to the third direction DR3 that is a normal direction to a plane defined by the first direction DR1 and the second direction DR2. The fourth direction DR4 may be defined as a direction opposite to the third direction DR3. In the specification, front surfaces (or upper surfaces) and rear surfaces (or lower surfaces) of members constituting the display device DD may be defined based on the third direction DR3.

The display device DD may include a display area DA and a non-display area NDA adjacent to the display area DA. The display area DA corresponds to a part on which an image is displayed. A plurality of pixel areas PXA may be disposed in the display area DA. The plurality of pixel areas PXA may be repeatedly disposed in the entirety of the display area DA.

In an embodiment, the plurality of pixel areas PXA may include a first pixel area PXA-R, a second pixel area PXA-G, and a third pixel area PXA-B, which are distinguished from each other. Although not illustrated, in an embodiment, the plurality of pixel areas PXA may further include a fourth pixel area (not illustrated) in addition to the first, second and third pixel areas PXA-R, PXA-G, and PXA-B. The first pixel area PXA-R, the second pixel area PXA-G, and the third pixel area PXA-B may emit lights having different wavelength ranges. In an embodiment, in an embodiment, the first pixel area PXA-R may be a red light-emitting area that emits a red light, the second pixel area PXA-G may be a green light-emitting area that emits a green light, and the third pixel area PXA-B may be a blue light-emitting area that emits a blue light, for example. In the specification, the first pixel area PXA-R may be also referred to as a red pixel area, the second pixel area PXA-G may be also referred to as a green pixel area, and the third pixel area PXA-B may be also referred to as a blue pixel area. However, the disclosure is not limited thereto, and the plurality of pixel areas PXA-R, PXA-G, and PXA-B may include a combination of pixel areas that emit other colors other than red, green, and blue described above.

The first, second and third pixel areas PXA-R, PXA-G, and PXA-B may be divided without overlapping each other when viewed in a plan view. A peripheral area NPXA is disposed around the first, second and third pixel areas PXA-R, PXA-G, and PXA-B. The peripheral area NPXA sets boundaries between the first, second and third pixel areas PXA-R, PXA-G, and PXA-B. The peripheral area NPXA may surround each of the first, second and third pixel areas PXA-R, PXA-G, and PXA-B. A structure that prevents color mixing between the first, second and third pixel areas PXA-R, PXA-G, and PXA-B, e.g., a pixel defining film PDL or a division pattern BMP, may be correspondingly disposed in the peripheral area NPXA. Further, even when the first, second and third pixel areas PXA-R, PXA-G, and PXA-B that are finally recognized on a front surface of the display device DD are not divided by the division pattern BMP or the like, the pixel areas may be divided by a printed layer such as a black matrix that defines the peripheral area NPXA or a laminated structure that has a light shielding function.

Referring to FIG. 2A, the first, second and third pixel areas PXA-R, PXA-G, and PXA-B may have a quadrangular shape in a plan view. However, the disclosure is not limited thereto, and in a plan view, the first, second and third pixel areas PXA-R, PXA-G, and PXA-B may have different polygonal shapes (including substantially polygonal shapes) such as a rhombus or a pentagon. The first, second and third pixel areas PXA-R, PXA-G, and PXA-B may have a quadrangular shape, e.g., rectangular shape, or a substantially quadrangular shape, e.g., substantially rectangular shape, having rounded corners in a plan view.

In the display device DD in an embodiment, the first, second and third pixel areas PXA-R, PXA-G, and PXA-B may be disposed in a stripe shape. Referring to FIGS. 1 and 2A, a plurality of first pixel areas PXA-R, a plurality of second pixel areas PXA-G, and a plurality of third pixel areas PXA-B may be disposed in the first direction DR1. Further, the first pixel area PXA-R, the second pixel area PXA-G, and the third pixel area PXA-B may be alternately disposed in the second direction DR2. That is, in the display device DD in an embodiment, the same pixel areas that emit lights having the same light-emitting wavelength may be disposed in the first direction DR1, and different pixels areas that emit lights having different light-emitting wavelengths may be repeatedly disposed in a predetermined order in the second direction DR2.

In FIG. 2A, the first pixel area PXA-R and the second pixel area PXA-G may have the same planar shape and area, and the third pixel area PXA-B may have the same shape as that of the first pixel area PXA-R and the second pixel area PXA-G but have an area that is smaller than that of the first pixel area PXA-R and the second pixel area PXA-G. However, the disclosure is not limited thereto, and the first, second and third pixel areas PXA-R, PXA-G, and PXA-B may have the same shape and the same area. Further, referring to FIG. 2B, unlike the second pixel area PXA-G illustrated in FIG. 2A, a second pixel area PXA-Ga may be divided into two parts in the first direction DR1.

Referring to FIG. 3A, the display device DD in an embodiment may

include a display panel DP and a light control panel OP disposed on the display panel DP. In an embodiment, a filling layer FML may be disposed between the display panel DP and the light control panel OP.

In an embodiment, the display panel DP may include a base layer BS, a circuit layer DP-CL disposed on the base layer BS, and a display element layer DP-ED disposed on the circuit layer DP-CL. Further, the display panel DP may include an encapsulation layer TFE disposed on the display element layer DP-ED. The display element layer DP-ED may include the pixel defining film PDL and a light-emitting element EMD. The encapsulation layer TFE may cover an upper portion of the display element layer DP-ED. The display element layer DP-ED may include a plurality of light-emitting areas EA1, EA2, and EA3. The light-emitting areas EA1, EA2, and EA3 of the display element layer DP-ED may correspond to the pixel areas PXA-R, PXA-G, and PXA-B (refer to FIG. 2A) of the display device DD, respectively.

In the display device DD in an embodiment, the display panel DP may

be a light-emitting display panel. In an embodiment, the display panel DP may be an organic electroluminescent display panel, for example.

When the display panel DP is an organic electroluminescent display panel, the display element layer DP-ED may include an organic electroluminescent element as the light-emitting element EMD. However, the disclosure is not limited thereto. In an embodiment, the display element layer DP-ED may include a quantum dot light-emitting diode as the light-emitting element EMD, for example. In an embodiment, the display element layer DP-ED may include a micro light-emitting diode (“LED”) element and/or a nano-LED element as the light-emitting element EMD, for example. The light-emitting element EMD may generate a source light. The source light generated and output from the light-emitting element EMD may be provided to the light control panel OP, and in a light control layer CCL of the light control panel OP, the source light may be converted into a light having a different wavelength or the source light may be scattered and pass therethrough.

In the display panel DP, the base layer BS may be a member that provides a base surface on which the display element layer DP-ED is disposed. The base layer BS may be a glass substrate, a metal substrate, a polymer substrate, or the like. However, the disclosure is not limited thereto, and the base layer BS may be an inorganic layer, an organic layer, or a composite material layer.

The base layer BS may have a multi-layered structure. In an embodiment, the base layer BS may have a three-layer structure of a polymer resin layer, an adhesive layer, and a polymer resin layer, for example. In particular, the polymer resin layer may include a polyimide-based resin. Further, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the specification, a “component-based” resin means a resin containing a functional group of the “component”.

The circuit layer DP-CL may be disposed on the base layer BS. The

circuit layer DP-CL may include an insulation layer, a semiconductor pattern, a conductive pattern, a signal line, or the like. The insulation layer, a semiconductor layer, and a conductive layer may be formed on the base layer BS in a manner such as coating and deposition, and thereafter, the insulation layer, the semiconductor layer, and the conductive layer may be selectively patterned through a plurality of photolithography processes. Thereafter, the semiconductor pattern, the conductive pattern, and the signal line included in the circuit layer DP-CL may be formed. In an embodiment, the circuit layer DP-CL may include a transistor, a buffer layer, and a plurality of insulation layers.

Referring to FIG. 3A, the light-emitting element EMD in an embodiment may include a first electrode EL1, a second electrode EL2 facing the first electrode EL1, and a light-emitting layer EML disposed between the first electrode EL1 and the second electrode EL2. The light-emitting layer EML included in the light-emitting element EMD may include an organic light-emitting material or a quantum dot as a light-emitting material. The light-emitting element EMD may further include a hole control layer HTR and an electron control layer ETR. Although not illustrated, the light-emitting element EMD may further include a capping layer (not illustrated) disposed on the second electrode EL2.

In an embodiment, the light-emitting element EMD may emit a light in a blue light-emitting area as a source light. Further, unlike this, in an embodiment, the light-emitting element EMD may emit a visible light in a wavelength range of about 480 nanometers (nm) to about 780 nm as the source light.

The pixel defining film PDL may be disposed on the circuit layer DP-CL and cover a portion of the first electrode EL1. A light-emitting opening OH is defined in the pixel defining film PDL. At least a portion of the first electrode EL1 is exposed through the light-emitting opening OH of the pixel defining film PDL. In an embodiment, the light-emitting areas EA1, EA2, and EA3 may be defined to correspond to partial areas of the first electrode EL1, which is exposed through the light-emitting opening OH.

In the light-emitting element EMD, the first electrode EL1 is disposed on the circuit layer DP-CL. The first electrode EL1 may be an anode or a cathode. Further, the first electrode EL1 may be a pixel electrode. The first electrode EL1 may be a transmissive electrode, a semi-transmissive electrode, or a reflective electrode.

The hole control layer HTR may be disposed between the first electrode EL1 and the light-emitting layer EML. The hole control layer HTR may include at least one of a hole injection layer, a hole transport layer, and an electron blocking layer. The hole control layer HTR may be disposed as a common layer to overlap the light-emitting areas EA1, EA2, and EA3, and the entirety of the pixel defining film PDL that divides the light-emitting areas EA1, EA2, and EA3. However, the disclosure is not limited thereto, and the hole control layer HTR may be patterned and provided to be separately disposed to correspond to the light-emitting areas EA1, EA2, and EA3.

The light-emitting layer EML is disposed on the hole control layer HTR. In an embodiment, the light-emitting layer EML may be provided as a common layer to overlap the light-emitting areas EA1, EA2, and EA3, and the entirety of the pixel defining film PDL that divides the light-emitting areas EA1, EA2, and EA3. In an embodiment, the light-emitting layer EML may emit a blue light. In the display device DD in an embodiment, the blue light may be the source light.

The light-emitting layer EML may overlap the entirety of the hole

control layer HTR and the entirety of the electron control layer ETR. However, the disclosure is not limited thereto, and in an embodiment, the light-emitting layer EML may be disposed inside the light-emitting opening OH. That is, the light-emitting layer EML may be separately formed to correspond to the light-emitting areas EA1, EA2, and EA3 divided by the pixel defining film PDL. The light-emitting layer EML separately formed to correspond to the light-emitting areas EA1, EA2, and EA3 all may emit a light having the same wavelength range or may emit lights having different wavelength ranges through the light-emitting areas EA1, EA2, and EA3.

The light-emitting layer EML may have a multi-layer structure having a single layer consisting of a single material, a single layer consisting of a plurality of different materials, or a plurality of layers consisting of a plurality of different materials from each other. The light-emitting layer EML may include a fluorescent or phosphorescent material. In the light-emitting element EMD in an embodiment, the light-emitting layer EML may include a light-emitting material such as an organic light-emitting material, a metal organic complex, or a quantum dot.

The electron control layer ETR may be disposed between the light-emitting layer EML and the second electrode EL2. The electron control layer ETR may include at least one of an electron injection layer, an electron transport layer, and a hole blocking layer. Referring to FIG. 3A, the electron control layer ETR may be disposed as a common layer to overlap the light-emitting areas EA1, EA2, and EA3, and the entirety of the pixel defining film PDL that divides the light-emitting areas EA1, EA2, and EA3. However, the disclosure is not limited thereto, and the electron control layer ETR may be patterned and provided to be separately disposed to correspond to the light-emitting areas EA1, EA2, and EA3.

The second electrode EL2 is provided on the electron control layer ETR. The second electrode EL2 may be a common electrode. The second electrode EL2 may be a cathode or an anode, but the disclosure is not limited thereto. In an embodiment, when the first electrode EL1 is the anode, the second electrode EL2 may be the cathode, or when the first electrode EL1 is the cathode, the second electrode EL2 may be the anode, for example. The second electrode EL2 may be a transmissive electrode, a semi-transmissive electrode or a reflective electrode.

The encapsulation layer TFE may be disposed on the light-emitting element EMD. In an embodiment, in an embodiment, the encapsulation layer TFE may be disposed on the second electrode EL2, for example. Further, when the light-emitting element EMD includes the capping layer (not illustrated), the encapsulation layer TFE may be disposed on the capping layer (not illustrated). The encapsulation layer TFE may include at least one organic film and at least one inorganic film, and the inorganic film and the organic film may be arranged alternately. The encapsulation layer TFE may serve to protect the display element layer DP-ED from moisture/oxygen and prevent inflow of foreign substances such as dust particles.

The encapsulation layer TFE may include at least one inorganic film including at least one of a silicon nitride, a silicon oxy nitride, and a silicon oxide. Further, the inorganic film may include a titanium oxide, a aluminum oxide, or the like.

The encapsulation layer TFE may include an organic film disposed between the inorganic films. The organic film may include an organic polymer material including or consisting of an acrylate-based resin or the like. However, the disclosure is not limited thereto.

The display device DD in an embodiment of the disclosure may include the light control panel OP that is disposed on the display panel DP and includes the light control layer CCL. In an embodiment, the light control panel OP may further include a base substrate BL and a color filter layer CFL.

The light control layer CCL may include a light conversion body. The light conversion body may be a quantum dot, a fluorescent body, or the like. The light conversion body may convert a wavelength of the received light and emit the wavelength-converted light. That is, the light control layer CCL may be a layer including the quantum dot or a layer including the fluorescent body.

The light control layer CCL may include a plurality of light control patterns CCP1, CCP2, and CCP3. The light control layer CCL may include the first light control pattern CCP1 including a first quantum dot that converts a first color light that is a source light into a second color light, the second light control pattern CCP2 including a second quantum dot that converts the first color light into a third color light, and the third light control pattern CCP3 that transmits the first color light.

A plurality of openings BW-OH may be defined in the division pattern BMP. The plurality of openings BW-OH may be defined by a side wall of the division pattern BMP.

The light control patterns CCP1, CCP2, and CCP3 may be spaced apart from each other. The light control patterns CCP1, CCP2, and CCP3 may be spaced apart from each other by the division pattern BMP. The light control patterns CCP1, CCP2, and CCP3 may be disposed inside the openings BW-OH that are defined in the division pattern BMP. However, the disclosure is not limited thereto, and FIG. 3A illustrates that the division pattern BMP does not overlap the light control patterns CCP1, CCP2, and CCP3, but edges of the light control patterns CCP1, CCP2, and CCP3 may at least partially overlap the division pattern BMP.

The light control patterns CCP1, CCP2, and CCP3 may be parts that convert a wavelength of a light provided by the display element layer DP-ED or transmit the provided light. The light control patterns CCP1, CCP2, and CCP3 may be formed by an inkjet printing method. The light control patterns CCP1, CCP2, and CCP3 may be formed as a liquid ink composition is provided in the openings BW-OH and the provided ink composition is polymerized by a thermal curing process or a photo-curing process. In an embodiment of the disclosure, the first and second light control patterns CCP1 and CCP2 may be formed by an inkjet printing method, and the third light control pattern CCP3 may be formed by an exposure process.

In the display device DD in an embodiment, the light-emitting element EMD may provide the first color light. In an embodiment, the first color light may be a blue light. In the light control layer CCL in an embodiment, the first light control pattern CCP1 may include a red quantum dot that converts the first color light provided by the light-emitting element EMD into a red light that is the second color light, and the second light control pattern CCP2 may include a green quantum dot that converts the first color light provided by the light-emitting element EMD into a green light that is the third color light, for example. The third light control pattern CCP3 may transmit the first color light provided by the light-emitting element EMD and may not include a quantum dot.

In the specification, the quantum dot refers to a crystal of a semiconductor compound. The quantum dot may emit lights having various light-emitting wavelengths depending on a size of the crystal. The quantum dot may emit lights having various light-emitting wavelengths by adjusting an element ratio in a compound of the quantum dot.

A diameter of the quantum dot may be in a range of, e.g., about 1 nm to about 10 nm. The quantum dot may be synthesized by a wet chemical process, a metal organic chemical vapor deposition (“MOCVD”) process, a molecular beam epitaxy (“MBE”) process, or similar processes.

The wet chemical process is a method of growing quantum dot particle crystals after mixing an organic solvent and a precursor material. When the crystals are grown, the organic solvent may naturally serve as a dispersant coordinated to a quantum dot crystal surface and may adjust the growth of the crystals. Thus, in the wet chemical process, the growth of the quantum dot particles may be controlled through a process that is easier and cheaper than a vapor deposition method such as the MOCVD or the MBE.

The quantum dot may include a group III-VI semiconductor compound, a group II-VI semiconductor compound, a group III-V semiconductor compound, a group I-III-VI semiconductor compound, a group IV-VI semiconductor compound, a group IV element or compound, or any combinations thereof.

In embodiments, the group II-VI semiconductor compound may include binary compounds such as CdS, CdSe, CdTe, ZnS, ZnSe, ZnTe, ZnO, HgS, HgSe, HgTe, MgSe, and MgS, ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS, quaternary compounds such as CdZnSeS, CdZnSeTe, CdZnSTe, CdHgSeS, CdHgSeTe, CdHgSTe, HgZnSeS, HgZnSeTe, and HgZnSTe, or any combinations thereof. The group II-VI semiconductor compound may further include a group I metal and/or a group IV element. A group I-II-VI compound may be selected from CuSnS or CuZnS, and a group II-IV-VI compound may be selected from ZnSnS or the like. A group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and combinations thereof.

In embodiments, the group III-V semiconductor compound may include binary compounds such as GaN, GaP, GaAs, GaSb, AlN, AlP, AlAs, AlSb, InN, InP, InAs, and InSb, ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb, quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, or any combinations thereof. The group III-V semiconductor compound may further include a group II element. In embodiments, the group III-V semiconductor compound further including the group II element may include InZnP, InGaZnP, InAlZnP, or the like.

Example of the group III-VI semiconductor compound may include binary compounds such as GaS, GazS₃, GaSe, GazSe₃, GaTe, InS, InSe, In₂Se₃, and InTe, ternary compounds such as InGaS₃ and InGaSe₃, or any combinations thereof.

In embodiments, the group I-III-VI semiconductor compound may include ternary compounds such as AgIn_{S}, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂, quaternary compounds such as AgInGaS₂ and AgInGaSe₂, or any combinations thereof.

In embodiments, the group IV-VI semiconductor compound may include binary compounds such as SnS, SnSe, SnTe, PbS, PbSe, and PbTe, ternary compounds such as SnSeS, SnSeTe, SnSTe, PbSeS, PbSeTe, PbSTe, SnPbS, SnPbSe, and SnPbTe, quaternary compounds such as SnPbSSe, SnPbSeTe, and SnPbSTe, or any combinations thereof.

In embodiments, the group II-IV-V semiconductor compound may be a ternary compound selected from the group consisting of ZnSnP, ZnSnP₂, ZnSnAs₂, ZnGeP₂, ZnGeAs₂, CdSnP₂, and CdGeP₂, and combinations thereof.

The group IV element or compound may include single element compounds such as Si and Ge, binary compounds such as SiC and SiGe, or any combinations thereof.

Elements included in a multi-element compound such as the binary compound, the ternary compound, and the quaternary compound may be inside particles at a uniform concentration or a non-uniform concentration. That is, the chemical formula means the type of elements included in the compound, and an element ratio in the compound may be different. In an embodiment, AgInGaS2 may mean AgInₓGa₍₁₋ₓ₎S₂ (x is a real number between 0 and 1), for example.

The quantum dot may have a single structure or a core-shell dual structure in which the concentrations of elements included in the corresponding quantum dot are uniform. In an embodiment, a material included in the core and a material included in the shell may be different from each other, for example.

The shell of the quantum dot may serve as a protective layer for maintaining semiconductor properties by preventing changes of chemical properties of the core and/or as a charging layer for providing electrophoretic properties to the quantum dot. The shell may be a single layer or a multi-layer. The core/shell structure may have a concentration gradient in which the concentration of the element that is in the shell decreases toward the core.

In embodiments, the shell of the quantum dot may include a metal or non-metal oxide, a semiconductor compound, or any combinations thereof. In embodiments, the metal or non-metal oxide may include binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, ternary compounds such as MgAl₂O₄, CoFe₂O₄, NiFe₂O₄, and CoMn₂O₄, or any combinations thereof. In embodiments, the semiconductor compound may include the group III-VI semiconductor compound, the group II-VI semiconductor compound, the group III-V semiconductor compound, the group I-III-VI semiconductor compound, the group IV-VI semiconductor compound, or any combinations thereof, as described in the specification. In an embodiment, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb or any combinations thereof, for example.

Elements included in a multi-element compound such as the binary compound and the ternary compound may be inside particles at a uniform concentration or a non-uniform concentration. That is, the chemical formula means the type of elements included in the compound, and an element ratio in the compound may be different.

The quantum dot may have a full width of half maximum (“FWHM”) of a light-emitting wavelength spectrum of about 45 nm or less, specifically about 40 nm or less, and more specifically about 30 nm or less, and the color purity and color reproducibility may be improved in this range. Further, since a light emitted through this quantum dot is emitted in all directions, an optical viewing angle may be improved.

Further, a shape of the quantum dot may specifically include a spherical shape, a pyramid shape, a multi-arm shape, or cubic nano-particles, nano-tubes, nano-wires, nano-fibers, nano-plate-shaped particles, or the like.

Since an energy band gap may be adjusted by adjusting the size of the quantum dot or adjusting an element ratio in the quantum dot compound, lights having various wavelengths may be obtained in a quantum dot light-emitting layer. Thus, by the above-described quantum dot (using quantum dots having different sizes or having different element ratios in the quantum dot compound), the light-emitting element that emits the lights having various wavelengths may be implemented. In detail, the adjustment of the size of the quantum dot or the element ratio in the quantum dot compound may be selected so that the red light, the green light, and/or the blue light are emitted. Further, the quantum dot may combine lights having various colors to emit a white light.

The first, second and third light control patterns CCP1, CCP2, and CCP3 may further include scatterers. In an embodiment, the third light control pattern CCP3 may not include the quantum dot and may include the scatterer, for example.

The scatterer may be a particle having a different refractive index from that of a light-transmitting resin, e.g., a light scattering particle. A material of the scatterer is not particularly limited as long as the material may partially scatter a transmitted light by forming an optical interface with a base resin, and the material thereof may be a metal oxide particle or an organic particle. The scatterer may include a titanium oxide (TiO₂), a zirconium oxide (ZrO₂), an aluminum oxide (Al₂O₃), an indium oxide (In₂O₃), a zinc oxide (ZnO), a tin oxide (SnO₂) or the like as a metal oxide. Further, the scatterer may include an acrylic resin or a urethane resin as an organic material. The scatterer may scatter a light in various directions regardless of an input angle without substantially converting a wavelength of an input light. Therefore, side visibility may be improved.

Each of the first light control pattern CCP1, the second light control pattern CCP2, and the third light control pattern CCP3 may include the base resin that disperses the quantum dot and the scatterer. In an embodiment, the first light control pattern CCP1 may include the first quantum dot and the scatterer dispersed in the base resin, the second light control pattern CCP2 may include the second quantum dot and the scatterer dispersed in the base resin, and the third light control pattern CCP3 may include the scatterer dispersed in the base resin.

The base resin, which is a medium in which the quantum dot and the scatterer are dispersed, may include or consist of various resin compositions that may generally be also referred to as binders. In an embodiment, the base resin may be an acrylic resin, a urethane resin, a silicone resin, an epoxy resin, or the like. The base resin may be a transparent resin, for example.

The light control layer CCL may further include a barrier layer (not illustrated) disposed at at least one of upper portions and lower portions of the light control patterns CCP1, CCP2, and CCP3. The barrier layer may serve to prevent penetration of moisture and/or oxygen (hereinafter, also referred to as ‘moisture/oxygen’). In an embodiment illustrated in FIG. 3A, the barrier layer may be disposed on the upper portions of the light control patterns CCP1, CCP2, and CCP3 adjacent to the color filter layer CFL. In an embodiment, the barrier layer may be disposed to cover upper surfaces of the light control patterns CCP1, CCP2, and CCP3 and the division pattern BMP. However, the disclosure is not limited thereto, and the barrier layer may be disposed under the light control patterns CCP1, CCP2, and CCP3 adjacent to the display panel DP to prevent the light control patterns CCP1, CCP2, and CCP3 from being exposed to moisture/oxygen.

In an embodiment of the display device DD according to the disclosure, the light control panel OP may include the color filter layer CFL disposed on the light control layer CCL. The color filter layer CFL may include filters CF1, CF2, and CF3. The color filter layer CFL may include the first filter CF1 that transmits the second color light, the second filter CF2 that transmits the third color light, and the third filter CF3 that transmits the first color light. In an embodiment, the first filter CF1 may be a red filter, the second filter CF2 may be a green filter, and the third filter CF3 may be a blue filter, for example.

Each of the first, second and third filters CF1, CF2, and CF3 may include a polymer photosensitive resin and a pigment or dye. The first filter CF1 may include a red pigment or dye, the second filter CF2 may include a green pigment or dye, and the third filter CF3 may include a blue pigment or dye. However, the disclosure is not limited thereto, and the third filter CF3 may not include pigment or dye. The third filter CF3 may include a polymer photosensitive resin and may not include pigment or dye. The third filter CF3 may be transparent. The third filter CF3 may include or consist of a transparent photosensitive resin.

The first, second and third filters CF1, CF2, and CF3 may be disposed to correspond to the first pixel area PXA-R, the second pixel area PXA-G, and the third pixel area PXA-B, respectively. Further, the first, second and third filters CF1, CF2, and CF3 may be disposed to correspond to the first, second and third light control patterns CCP1, CCP2, and CCP3, respectively. A part overlapping the first pixel area PXA-R may be defined as a first filter unit, a part overlapping the second pixel area PXA-G may be defined as a second filter unit, and a part overlapping the third pixel area PXA-B may be defined as a third filter unit.

Further, the plurality of filters CF1, CF2, and CF3 that transmit different color lights may overlap each other to correspond to the peripheral area NPXA disposed between the pixel areas PXA-R, PXA-G, and PXA-B. The plurality of filters CF1, CF2, and CF3 may be disposed to overlap each other in the third direction DR3 that is a thickness direction, to divide boundaries between the adjacent pixel areas PXA-R, PXA-G, and PXA-B. A portion in which the plurality of filters CF1, CF2, and CF3 is disposed to overlap each other may be also referred to as a light shielding unit BM. Unlike the illustration, the color filter layer CFL may further include a separate light shielding layer (not illustrate) that divides boundaries between the adjacent filters CF1, CF2, and CF3. Further, the light shielding layer (not illustrated) may be included in the color filter layer CFL to overlap the peripheral area NPXA instead of the light shielding unit BM in which the plurality of filters CF1, CF2, and CF3 is disposed to overlap each other. The light shielding layer (not illustrated) may be a blue filter or include an organic light shielding material or an inorganic light shielding material including black pigment or black dye.

The light shielding unit BM may be a portion corresponding to the peripheral area NPXA. As in a plan view illustrated in FIG. 2A, the pixel areas PXA-R, PXA-G, and PXA-B may be divided and defined by the light shielding unit BM. The pixel areas PXA-R, PXA-G, and PXA-B may correspond to the light control patterns CCP1, CCP2, and CCP3.

However, the disclosure is not limited thereto. In an embodiment, the first pixel area PXA-R adjacent in the first direction DR1 may be divided by the light shielding unit BM, and thus the arrangement of the pixel areas as illustrated in FIG. 2A may be displayed, for example. The pixel areas PXA-R, PXA-G, and PXA-B displayed on the display device DD may be divided by the light shielding unit BM or the division pattern BMP included in the light control layer CCL.

The color filter layer CFL may include a low refractive layer LR. The low refractive layer LR may be disposed between the light control layer CCL and the filters CF1, CF2, and CF3. The low refractive layer LR may be disposed on the light control layer CCL to prevent the light control patterns CCP1, CCP2, and CCP3 from being exposed to moisture/oxygen. Further, the low refractive layer LR may be disposed between the light control patterns CCP1, CCP2, and CCP3 and the filters CF1, CF2, and CF3 to function as an optical function layer that increases light extraction efficiency or prevents a reflective light from being input to the light control layer CCL. The low refractive layer LR may be a layer having a relatively low refractive index as compared to adjacent layers.

The low refractive layer LR may include at least one inorganic layer. In an embodiment, the low refractive layer LR may include or consist of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxy nitride or include a metal thin film having a secured light transmittance, for example. However, the disclosure is not limited thereto, and the low refractive layer LR may include an organic film. In an embodiment, the low refractive layer LR may include a polymer resin and inorganic particles, for example. The low refractive layer LR may include a single layer or multiple layers.

In the display device DD in an embodiment, the filters CF1, CF2, and CF3 of the color filter layer CFL may be directly disposed on the light control layer CCL. In this case, the low refractive layer LR may be omitted.

In an embodiment, the light control panel OP may further include the base substrate BL disposed on the color filter layer CFL. The base substrate BL may be a member that provides a base surface on which the color filter layer CFL and the light control layer CCL are disposed. The base substrate BL may be a glass substrate, a metal substrate, and a plastic substrate. However, the disclosure is not limited thereto, and the base substrate BL may be an inorganic layer, an organic layer, or a composite material layer. Further, unlike the illustration, in an embodiment, the base substrate BL may be omitted.

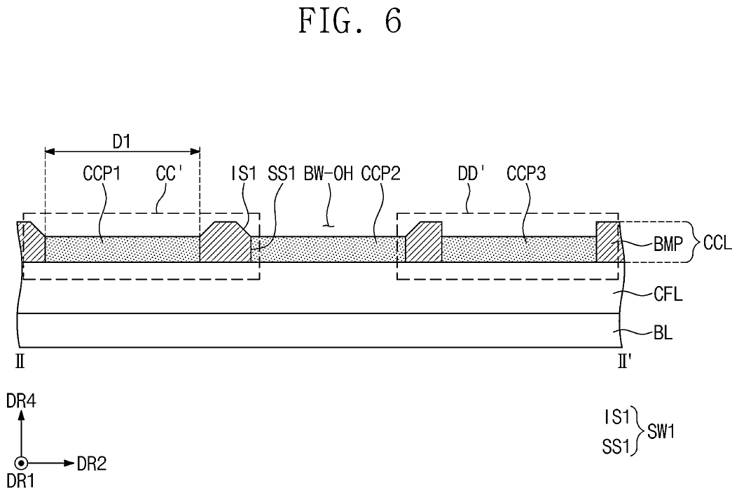

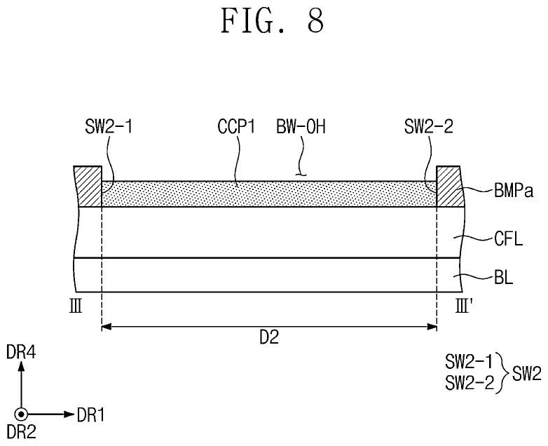

The light control layer CCL may include the division pattern BMP that divides the light control patterns CCP1, CCP2, and CCP3. As illustrated in FIG. 3A, when viewed in a plan view parallel to a plane defined by the second direction DR2 and the third direction DR3, the division pattern BMP that divides the light control patterns CCP1, CCP2, and CCP3 may include a plurality of side walls SW1 and SW2 (refer to FIGS. 6 and 8). A detailed content therefor will be described below. The light control patterns CCP1, CCP2, and CCP3 may be disposed in the openings BW-OH of the division pattern BMP.

Referring to FIG. 3B, a light control layer CCLa of a light control panel OPa of a display device DDa may include the plurality of light control patterns CCP1, CCP2, and CCP3. In an embodiment of the disclosure, the first, second and third light control patterns CCP1, CCP2, and CCP3 may be formed by an inkjet printing method. Further, each of the first, second and third light control patterns CCP1, CCP2, and CCP3 may include a quantum dot.

The division pattern BMP included in the light control layer CCLa may include inclined surfaces in all portions thereof adjacent to the plurality of light control patterns CCP1, CCP2, and CCP3.

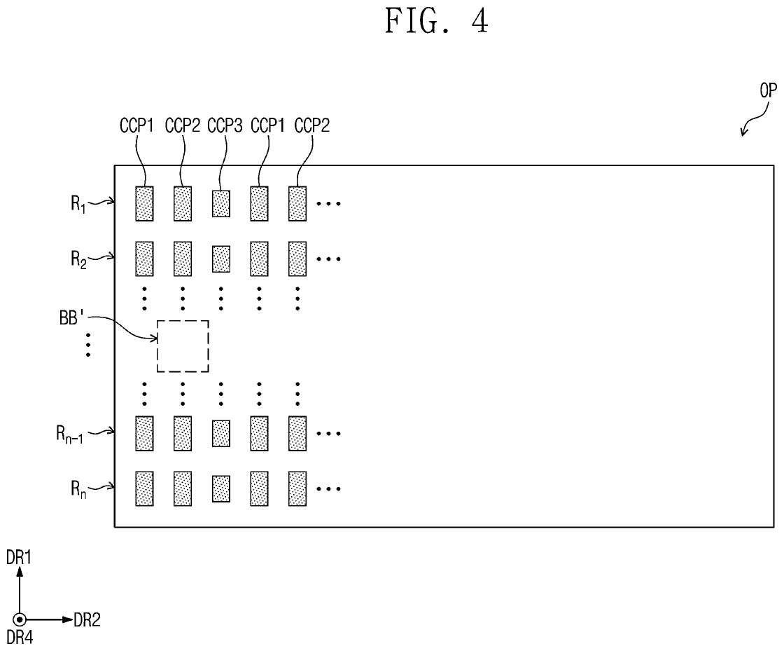

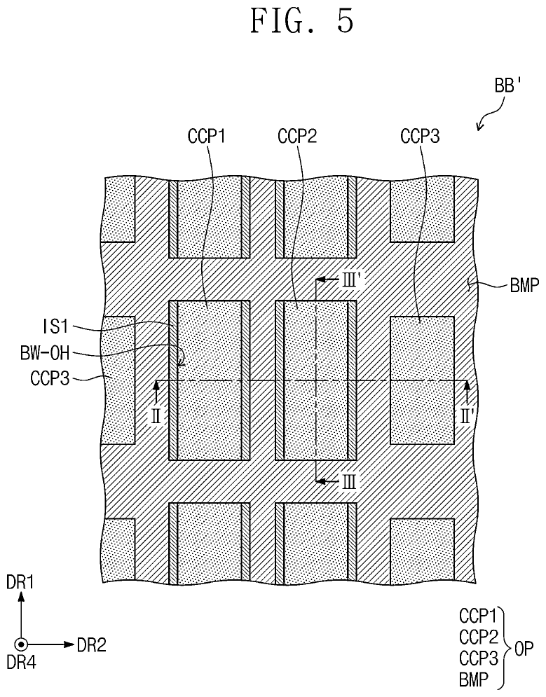

FIG. 4 is a plan view of an embodiment of a light control panel according to the disclosure, and FIG. 5 is a cross-sectional view of an embodiment of a portion of the light control panel according to the disclosure. In detail, FIG. 5 is an enlarged view of a portion corresponding to area BB′ of FIG. 4.

Referring to FIG. 4, the light control panel OP in an embodiment of the disclosure may include n first light control patterns CCP1 aligned in the first direction DR1, n second light control patterns CCP2 aligned in the first direction DR1, and n third light control patterns CCP3 aligned in the first direction DR1. The first, second and third light control patterns CCP1, CCP2, and CCP3 may be spaced apart from each other in the first direction DR1. Each of the first, second and third light control patterns CCP1, CCP2, and CCP3 may be disposed to have n rows R₁, R₂ . . . Rₙ. In an embodiment, n is an integer greater than or equal to 1, for example.

In an embodiment of the disclosure, the light control patterns may be disposed in an order of the first light control pattern CCP1, the second light control pattern CCP2, and the third light control pattern CCP3. The first, second and third light control patterns CCP1, CCP2, and CCP3 may emit lights having different wavelength ranges.

In the same row, the first light control pattern CCP1, the second light control pattern CCP2, and the third light control pattern CCP3 may be spaced apart from each other in the second direction DR2. In an embodiment, the first light control pattern CCP1, the second light control pattern CCP2, and the third light control pattern CCP3 may be disposed in this order, and the first light control pattern CCP1 may be disposed again after the third light control pattern CCP3, for example.

Referring to FIG. 5, the light control panel OP may include the first, second and third light control patterns CCP1, CCP2, and CCP3 and the division pattern BMP that divides the first, second and third light control patterns CCP1, CCP2, and CCP3. The openings BW-OH may be defined in the division pattern BMP. The first, second and third light control patterns CCP1, CCP2, and CCP3 may be disposed in the openings BW-OH.

The division pattern BMP may include a first inclined surface IS1. In detail, the first side wall SW1 (refer to FIG. 6) included in the division pattern BMP may include the first inclined surface IS1. A detailed description therefor will be described below.

The first, second and third light control patterns CCP1, CCP2, and CCP3 may correspond to the pixel areas PXA-R, PXA-G, and PXA-B (refer to FIG. 2A), respectively. The sizes of the first, second and third light control patterns CCP1, CCP2, and CCP3 may be the same as the sizes of the pixel areas PXA-R, PXA-G, and PXA-B. The size and shape of the first light control pattern and the second light control pattern CCP1 and CCP2 may be the same, the shape of the third light control pattern CCP3 may be the same as that of the first light control pattern and the second light control pattern CCP1 and CCP2 but the size of the third light control pattern CCP3 may be smaller than the size of the first light control pattern CCP1 and the second light control pattern CCP2.

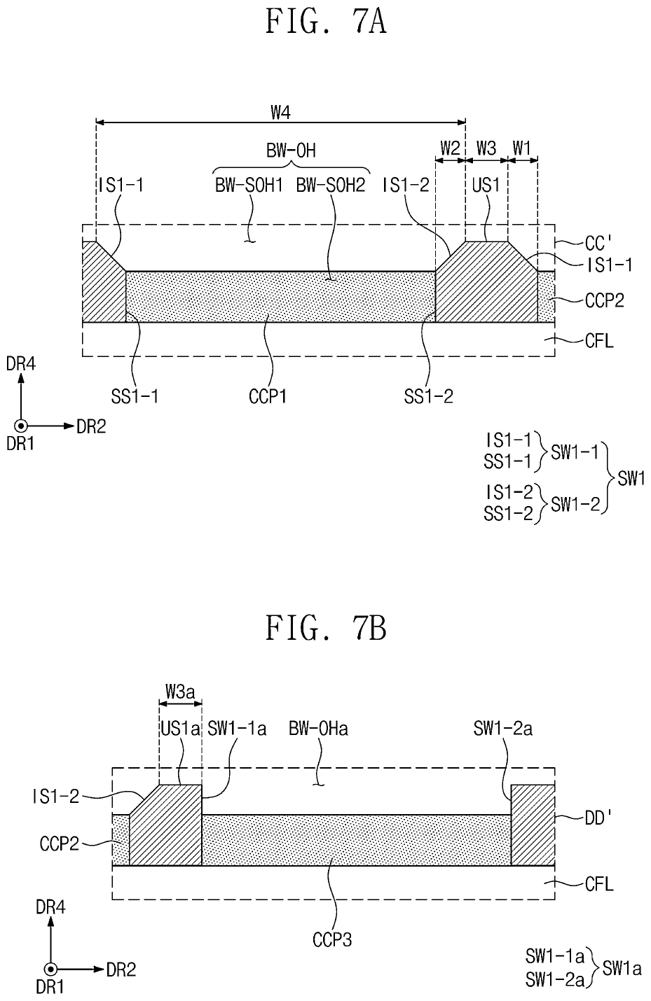

FIGS. 6 to 8 are enlarged cross-sectional views of an embodiment of a portion of the light control panel according to the disclosure. FIG. 6 is a cross-sectional view of the light control panel at a portion corresponding to line II-II' of FIG. 5. FIG. 7A is an enlarged view of area CC′ of FIG. 6. FIG. 7B is an enlarged view of area DD′ of FIG. 6. FIG. 8 is a cross-sectional view of the light control panel at a portion corresponding to line III-III′ of FIG. 5. Hereinafter, a description duplicated with the above description will be omitted.

Referring to FIG. 6, the color filter layer CFL may be disposed on the base substrate BL, and the light control layer CCL may be disposed on the color filter layer CFL. The light control layer CCL may include the division pattern BMP and the first, second and third light control patterns CCP1, CCP2, and CCP3 disposed in the openings BW-OH defined by the division pattern BMP.

The division pattern BMP may include the first side walls SW1 that face each other with one of the first, second and third light control patterns CCP1, CCP2, and CCP3 interposed therebetween and are spaced apart from each other in the second direction DR2. The first side walls SW1 may be spaced apart from each other by a first distance D1 in the second direction DR2. The first distance D1 may be the same as a width of one of the first, second and third light control patterns CCP1, CCP2, and CCP3 in the second direction DR2. In an embodiment, the first distance D1 may be in a range of about 27 micrometers (μm) or more and about 28 μm or less, for example. Although not illustrated, the first side walls SW1 may extend in the first direction DR1.

In an embodiment of the disclosure, the first side walls SW1 may include the first inclined surface IS1 inclined in a direction away from one of the first, second and third light control patterns CCP1, CCP2, and CCP3 and a first side surface SS1 extending from the first inclined surface IS1 and being in direct contact with the first, second and third light control patterns CCP1, CCP2, and CCP3. As illustrated, not all of the first side walls SW1 include the first inclined surface IS1, and first side walls SW1a (refer to FIG. 7B) adjacent to the third light control pattern CCP3 may not include the first inclined surface IS1.

Referring to FIG. 7A, the first side walls SW1 may include a (1-1)^{th} side wall SW1-1 and a (1-2)^{th} side wall SW1-2. The (1-1)^{th} side wall SW1-1 and the (1-2)^{th} side wall SW1-2 may be spaced apart from each other with the first light control pattern CCP1 interposed therebetween. The first distance D1 illustrated in FIG. 6 may be the same as a distance between the (1-1)^{th} side wall SW1-1 and the (1-2)^{th} side wall SW1-2. FIG. 7A illustrates the (1-1)^{th} side wall SW1-1 and the (1-2)^{th} side wall SW1-2 are spaced apart from each other with the first light control pattern CCP1 interposed therebetween, but the disclosure is not limited thereto, and as in FIG. 6, the (1-1)^{th} side wall SW1-1 and the (1-2)^{th} side wall SW1-2 are spaced apart from each other with the second light control pattern CCP2 interposed therebetween.

The (1-1)^{th} side wall SW1-1 may include a (1-1)^{th} inclined surface IS1-1 and a (1-1)^{th} side surface SS1-1. The (1-2)^{th} side wall SW1-2 may include a (1-2)^{th} inclined surface IS1-2 and a (1-2)^{th} side surface SS1-2. The (1-1)^{th} inclined surface IS1-1 and the (1-2)^{th} inclined surface IS1-2 may be spaced apart from each other with the first light control pattern CCP1 interposed therebetween. The (1-1)^{th} inclined surface IS1-1 and the (1-2)^{th} inclined surface IS1-2 may be symmetrical to each other with the first light control pattern CCP1 interposed therebetween. The (1-1)^{th} inclined surface IS1-1 and the (1-2)^{th} inclined surface IS1-2 may not contact the first light control pattern CCP1. The (1-1)^{th} inclined surface IS1-1 and the (1-2)^{th} inclined surface IS1-2 may be inclined in directions away from each other with respect to the first light control pattern CCP1.

The (1-1)^{th} side surface SS1-1 and the (1-2)^{th} side surface SS1-2 may be spaced apart from each other with the first light control pattern CCP1 interposed therebetween. The (1-1)^{th} side surface SS1-1 and the (1-2)^{th} side surface SS1-2 may be symmetrical to each other with the first light control pattern CCP1 interposed therebetween. The (1-1)^{th} side surface SS1-1 and the (1-2)^{th} side surface SS1-2 may be in direct contact with the first light control pattern CCP1. Unlike the illustration, only portions of the (1-1)^{th} side surface SS1-1 and the (1-2)^{th} side surface SS1-2 may be in direct contact with the first light control pattern CCP1.

The first side walls SW1 may further include a first upper surface US1 that connects the (1-1)^{th} side wall SW1-1 and the (1-2)^{th} side wall SW1-2. The first upper surface US1 may extend from each of the (1-1)^{th} inclined surface IS1-1 and the (1-2)^{th} inclined surface IS1-2. The first upper surface US1 may correspond to an upper surface of the division pattern BMP (refer to FIG. 6). The first upper surface US1 may not overlap the first, second and third light control patterns CCP1, CCP2, and CCP3 in a plan view. In an embodiment of the disclosure, the (1-1)^{th} inclined surface IS1-1 and the (1-2)^{th} inclined surface IS1-2 may have non-liquid repellent properties. Further, the (1-1)^{th} side surface SS1-1 and the (1-2)^{th} side surface SS1-2 may have non-liquid repellent properties. However, the first upper surface US1 may have liquid-repellent properties.

A width of the (1-1)^{th} inclined surface IS1-1 in the second direction DR2 may be defined as a first width W1, a width of the (1-2)^{th} inclined surface IS1-2 in the second direction DR2 may be defined as a second width W2, and a width of the first upper surface US1 in the second direction DR2 may be defined as a third width W3. In an embodiment of the disclosure, the first width W1 and the second width W2 may be the same. In an embodiment, the first width W1 and the second width W2 may be in a range of about 3.5 μm or more and about 4.0 μm or less, for example. The third width W3 may be greater than the first width W1 and the second width W2. The third width W3 may be smaller than a sum of the first width W1 and the second width W2. In an embodiment, the third width W3 may be in a range of about 6 μm or more and about 7 μm or less, for example. A sum of the first width W1 to the third width W3 may be in a range of the about 13 μm or more and about 15 μm or less. The sum of the first width W1 to the third width W3 may be the same as a distance between two adjacent light control patterns among the first, second and third light control patterns CCP1, CCP2, and CCP3 illustrated in FIG. 6.

In an embodiment of the disclosure, the openings BW-OH may include a first sub-opening BW-SOH1 defined by the (1-1)^{th} inclined surface IS1-1 and the (1-2)^{th} inclined surface IS1-2 and a second sub-opening BW-SOH2 defined by the (1-1)^{th} side surface SS1-1 and the (1-2)^{th} side surface SS1-2. A width of the first sub-opening BW-SOH1 in the second direction DR2 may gradually increase in the fourth direction DR4. That is, the width of the first sub-opening BW-SOH1 in the second direction DR2 may gradually decrease toward the second sub-opening BW-SOH2. A maximum width W4 of the first sub-opening BW-SOH1 in the second direction DR2 may be in a range of about 34.8 μm or more and about 35.8 μm or less.

A width of the second sub-opening BW-SOH2 in the second direction DR2 may be constant in the fourth direction DR4. However, the disclosure is not limited thereto, and a width the second sub-opening BW-SOH2 in the second direction DR2 may gradually decrease in the fourth direction DR4.

Referring to FIGS. 5 to 7A, the first side walls SW1 adjacent to the first and second light control patterns CCP1 and CCP2 may include the first inclined surface IS1 that is inclined in directions away from the first and second light control patterns CCP1 and CCP2. When a process is conducted by an inkjet printing method, a minimum width of the process may be about 34.0 μm or more. When the first and second light control patterns CCP1 and CCP2 are formed through an inkjet process, as the first side walls SW1 adjacent to the first and second light control patterns CCP1 and CCP2 include the first inclined surface IS1, even in a high-resolution design having the first distance D1 and a relatively small separation distance between the light control patterns CCP1 and CCP2 in the second direction DR2, a process margin for securing printing quality of the first and second light control patterns CCP1 and CCP2 may be secured. As a result, the display device DD (refer to FIG. 1) capable of a fine inkjet process may be provided.

Referring to FIG. 7B, the first side walls (or non-inclined side walls) SW1a may include a (1-1)^{th} side wall SW1-1a and a (1-2)^{th} side wall SW1-2a. The (1-1)^{th} side wall SW1-1a and the (1-2)^{th} side wall SW1-2a may be spaced apart from each other with the third light control pattern CCP3 interposed therebetween. Openings BW-OHa may be defined by the (1-1)^{th} side wall SW1-1a and the (1-2)^{th} side wall SW1-2a. The third light control pattern CCP3 may be disposed in the openings BW-OHa.

In an embodiment of the disclosure, the (1-1)^{th} side wall SW1-1a and the (1-2)^{th} side wall SW1-2a may not include the first inclined surface IS1 illustrated in FIG. 6. That is, the first side walls SW1a adjacent to the third light control pattern CCP3 may not include the first inclined surface IS1. Unlike the first and second light control patterns CCP1 and CCP2 (refer to FIG. 6), the third light control pattern CCP3 may be formed through an exposure process. Thus, since a fine inkjet process is not desired, the first side walls SW1a may not include the first inclined surface IS1.

The first side walls SW1a may further include a first upper surface US1a that connects the (1-2)^{th} inclined surface IS1-2 and the (1-1)^{th} side wall SW1-1a. A width of the first upper surface US1a in the second direction DR2 may be defined as a third width W3a. The third width W3 of the first upper surface US1 may be the same as the third width W3a of the first upper surface US1a illustrated in FIG. 7B. In an embodiment, the third width W3a may be in a range of about 6 μm or more and about 7 μm or less, for example.

Referring to FIGS. 5 and 8, the division pattern BMP may include the second side walls SW2 that face each other with one of the first, second and third light control patterns CCP1, CCP2, and CCP3 interposed therebetween and are spaced apart from each other in the first direction DR1. The second side walls SW2 may be spaced apart from each other by a second distance D2 in the first direction DR1. The second distance D2 may be the same as a width of the first light control pattern CCP1 in the first direction DR1. The second distance D2 may be greater than the first distance D1 of FIG. 6. In an embodiment, the second distance D2 may be in a range of about 80 um or more and about 90 μm or less, for example. Although not illustrated, the second side walls SW2 may extend in the second direction DR2.

In an embodiment of the disclosure, the second side walls SW2 may include a (2-1)^{th} side wall SW2-1 and a (2-2)^{th} side wall SW2-2. The (2-1)^{th} side wall SW2-1 and the (2-2)^{th} side wall SW2-2 may be spaced apart from each other with the first light control pattern CCP1 interposed therebetween. The second distance D2 illustrated in FIG. 8 may be the same as a distance between the (2-1)^{th} side wall SW2-1 and the (2-2)^{th} side wall SW2-2. The (2-1)^{th} side wall SW2-1 and the (2-2)^{th} side wall SW2-2 may not include the first inclined surface IS1 illustrated in FIG. 6. That is, the (2-1)^{th} side wall SW2-1 and the (2-2)^{th} side wall SW2-2 spaced apart from each other by the second distance D2 in the first direction DR1 may not include the first inclined surface IS1.

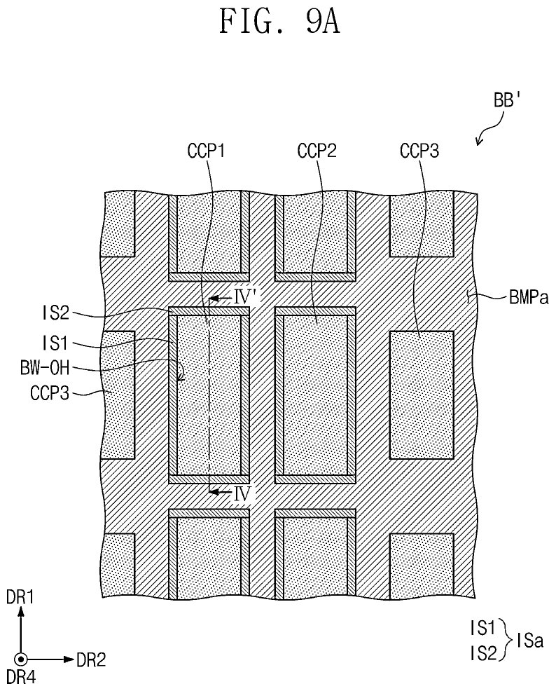

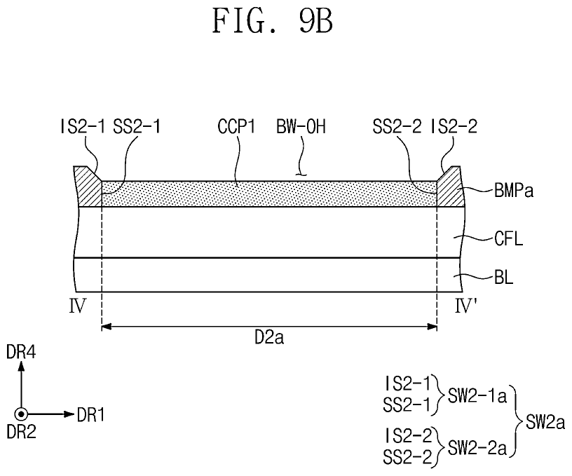

FIG. 9A is a cross-sectional view of an embodiment of the portion of the light control panel according to the disclosure. FIG. 9B is a cross-sectional view of the light control panel at a portion corresponding to line IV-IV′ of FIG. 9A. FIG. 9A is an enlarged view of an embodiment of a portion corresponding to area BB′ of FIG. 4.

Referring to FIG. 9A, a division pattern BMPa may include an inclined surface ISa. The inclined surface ISa may include the first inclined surface IS1 and a second inclined surface IS2. In detail, the first side walls SW1 (refer to FIG. 6) included in the division pattern BMP may include the first inclined surface IS1, and second side walls SW2a (refer to FIG. 9B) may include the second inclined surface IS2. Unlike FIG. 6, in FIG. 9A, the division pattern BMPa may further include the second inclined surface IS2. Thus, the description will be made while focusing on the second inclined surface IS2.

Referring to FIG. 9B, the second side walls SW2a may include a (2-1)^{th} side wall SW2-1a and a (2-2)^{th} side wall SW2-2a. The (2-1)^{th} side wall SW2-1a and the (2-2)^{th} side wall SW2-2a may be spaced apart from each other with the first light control pattern CCP1 interposed therebetween. The (2-1)^{th} side wall SW2-1a and the (2-2)^{th} side wall SW2-2a may be spaced apart from each other by a second distance D2a. The second distance D2a may be the same as a width of one of the first light control patterns CCP1 in the first direction DR1. In an embodiment, the second distance D2a may be in a range of about 80 μm or more and about 90 μm or less, for example. Although not illustrated, the second side walls SW2a may extend in the second direction DR2.

The (2-1)^{th} side wall SW2-1a may include a (2-1)^{th} inclined surface IS2-1 and a (2-1)^{th} side surface SS2-1. The (2-2)^{th} side wall SW2-2a may include a (2-2)^{th} inclined surface IS2-2 and a (2-2)^{th} side surface SS2-2. The (2-1)^{th} inclined surface IS2-1 and the (2-2)^{th} inclined surface IS2-2 may be spaced apart from each other with the first light control pattern CCP1 interposed therebetween. The (2-1)^{th} inclined surface IS2-1 and the (2-2)^{th} inclined surface IS2-2 may be symmetrical to each other with the first light control pattern CCP1 interposed therebetween. The (2-1)^{th} inclined surface IS2-1 and the (2-2)^{th} inclined surface IS2-2 may not contact the first light control pattern CCP1. The (2-1)^{th} inclined surface IS2-1 and the (2-2)^{th} inclined surface IS2-2 may be inclined in directions away from each other with respect to the first light control pattern CCP1.

The (2-1)^{th} side surface SS2-1 and the (2-2)^{th} side surface SS2-2 may be spaced apart from each other with the first light control pattern CCP1 interposed therebetween. The (2-1)^{th} side surface SS2-1 and the (2-2)^{th} side surface SS2-2 may be symmetrical to each other with the first light control pattern CCP1 interposed therebetween. The (2-1)^{th} side surface SS2-1 and the (2-2)^{th} side surface SS2-2 may be in direct contact with the first light control pattern CCP1. Unlike the illustration, only portions of the (2-1)^{th} side surface SS2-1 and the (2-2)^{th} side surface SS2-2 may be in direct contact with the first light control pattern CCP1.

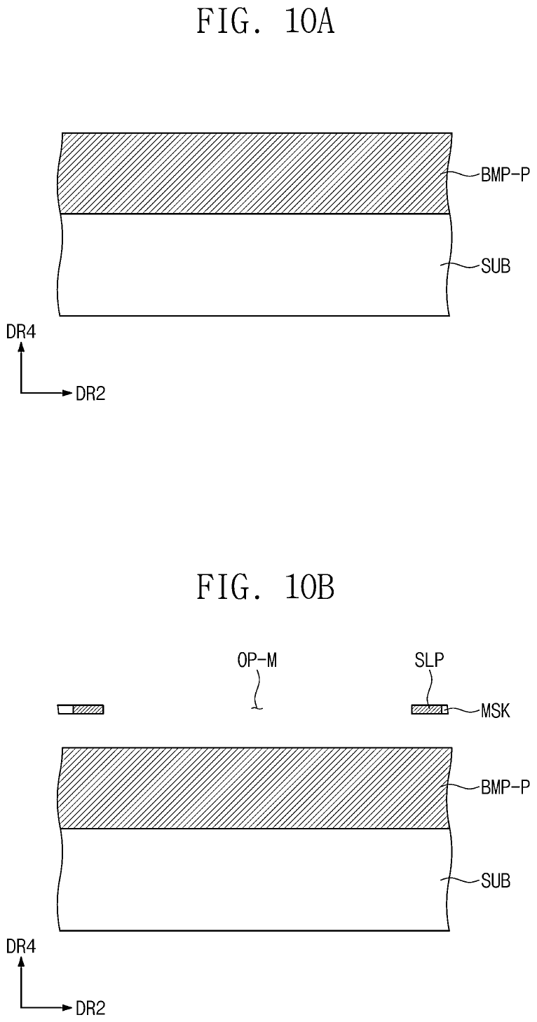

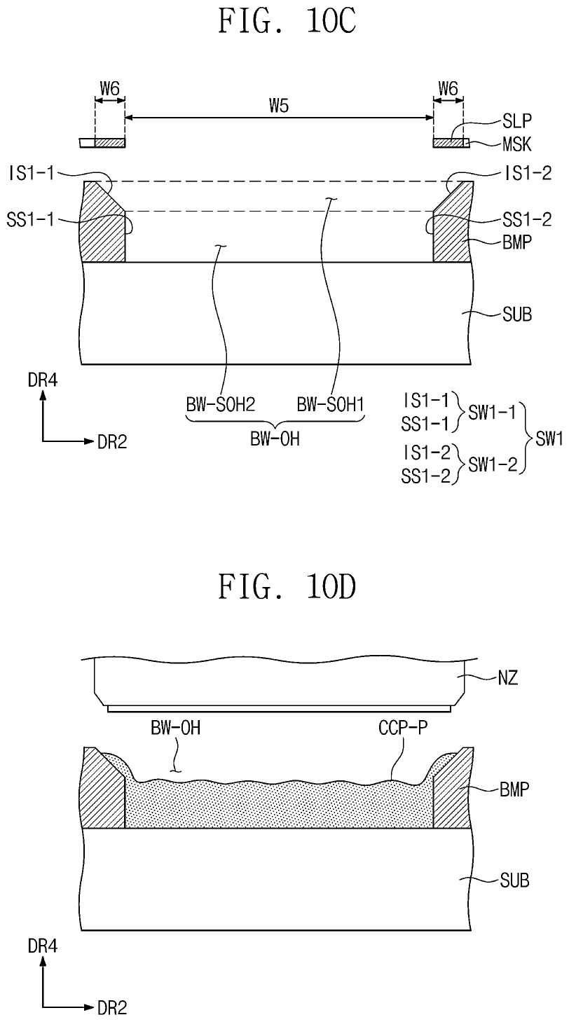

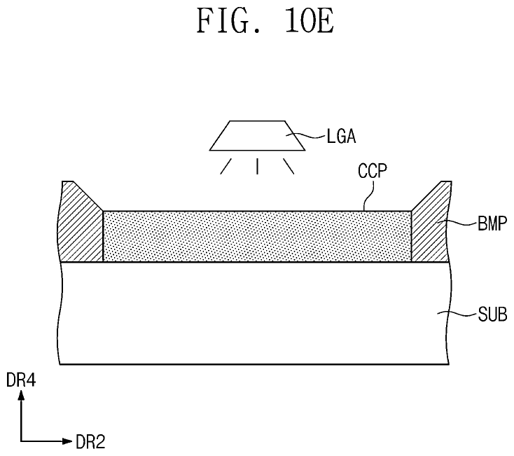

FIGS. 10A to 10E are schematic views illustrating an embodiment of operations of a method of manufacturing a portion of the display device according to the disclosure. Hereinafter, a method of manufacturing the light control panel OP included in the display device DD (refer to FIG. 1) will be described with reference to FIGS. 10A to 10E. Hereinafter, in FIGS. 10A to 10E, some of operations of manufacturing the display device DD illustrated in FIG. 3A in an embodiment of the disclosure will be illustrated and described as examples.

Referring to FIG. 10A, a preliminary division pattern BMP-P may be disposed on a base member SUB. In the method of manufacturing a display device according to the disclosure, the base member SUB may include the base substrate BL (refer to FIG. 3A) and the color filter layer CFL (refer to FIG. 3A) disposed on the base substrate BL (refer to FIG. 3A).

Referring to FIGS. 10B and 10C, an operation of arranging a mask MSK on the preliminary division pattern BMP-P and patterning the preliminary division pattern BMP-P through the mask MSK may be performed. The mask MSK may be a half tone mask that includes areas having different light transmittances within the mask MSK. The opening BW-OH may be defined in the preliminary division pattern BMP-P through a mask opening OP-M and a slit part SLP formed in the mask MSK. The slit part SLP may have relatively low light transmittance. Accordingly, a patterning shape of the preliminary division pattern BMP-P may be changed. The (1-1)^{th} inclined surface IS1-1 and the (1-2)^{th} inclined surface IS1-2 may be formed in a portion that overlaps the slit part SLP in a plan view.

The opening BW-OH including the first sub-opening BW-SOH1 and the second sub-opening BW-SOH2 may be defined by adjusting the patterning through the mask MSK including the slit part SLP. That is, the division pattern BMP in which the opening BW-OH is defined may be formed. A width W5 of the mask opening OP-M in the second direction DR2 may be the same as a width of the second sub-opening BW-SOH2 in the second direction DR2. Further, a width W6 of the slit part SLP may be the same as a width of the (1-1)^{th} inclined surface IS1-1 and the (1-2)^{th} inclined surface IS1-2 in the second direction DR2. Through the patterning process, the (1-1)^{th} inclined surface IS1-1 and the (1-2)^{th} inclined surface IS1-2 may have non-liquid repellent properties

Referring to FIG. 10D, an ink composition CCP-P may be provided in the opening BW-OH through an inkjet process. In detail, the ink composition CCP-P may be provided in the opening BW-OH through a nozzle NZ of an inkjet printing machine. The ink composition CCP-P may include a base monomer, a quantum dot, and a scatterer. Although not illustrated, in manufacturing the third light control pattern CCP3 (refer to FIG. 3A), the ink composition may include the base monomer and the scatterer and may not include the quantum dot.

In the ink composition CCP-P, hexamethylene diacrylate, tetraethylene glycol diacrylate, dipropylene glycol diacrylate, tripropylene glycol diacrylate, or the like may be used as the base monomer. However, the disclosure is not limited thereto, and monomers that do not affect light-emitting properties of the quantum dot and are capable of polymerization may be used without limitation.

The ink composition CCP-P may be provided to overlap the (1-1)^{th} inclined surface IS1-1 and the (1-2)^{th} inclined surface IS1-2. The ink composition CCP-P provided on the (1-1)^{th} inclined surface IS1-1 and the (1-2)^{th} inclined surface IS1-2 may flow down from the (1-1)^{th} inclined surface IS1-1 and the (1-2)^{th} inclined surface IS1-2 and may be provided inside the second sub-opening BW-SOH2 (refer to FIG. 10C). Accordingly, a sufficient amount of the ink composition CCP-P may be uniformly provided in the entirety of the openings BW-OH without an area of the opening BW-OH, to which the ink composition CCP-P is not applied. Further, the ink composition CCP-P may be disposed in the openings BW-OH having a relatively small width, thereby securing a process margin for securing printing quality.

Referring to FIG. 10E, an operation of curing the ink composition CCP-P may be performed. A light control pattern CCP may be provided by curing the ink composition CCP-P by irradiating the ink composition CCP-P with ultraviolet rays emitted from a light generation unit LGA. The light control pattern CCP may be one of the first and second light control patterns CCP1 and CCP2 illustrated in FIG. 3A. However, the disclosure is not limited thereto, and the operation of curing the ink composition CCP-P may be performed by a thermal curing process or may be omitted.

A light control panel included in a display device of the disclosure may include light control patterns and a division pattern that divides the light control patterns. The division pattern may include a plurality of side walls, and an inclined surface inclined in a direction away from the light control patterns may be formed on a side wall adjacent to the light control patterns. When the light control patterns are formed through an inkjet process, a sufficient process margin may be secured so that the light control patterns having a relatively small width may be formed through the inkjet process. As a result, the display device capable of a fine inkjet process may be provided.

Although the description has been made above with reference to an embodiment of the disclosure, it may be understood that those skilled in the art or those having ordinary knowledge in the art may variously modify and change the disclosure without departing from the spirit and technical scope of the disclosure described in the appended claims.

Thus, the technical scope of the disclosure is not limited to the detailed description of the specification, but should be defined by the appended claims.

What is claimed is:

1. A display device comprising:
a display panel including a plurality of light-emitting elements configured to emit a source light; and
a light control layer disposed on the display panel and including:
a plurality of light control patterns; and
a division pattern which divides the plurality of light control patterns and in which a plurality of openings in which the plurality of light control patterns is arranged is defined, the division pattern including:
a plurality of side walls which define the plurality of openings, the plurality of side walls including:
first side walls extending in a first direction, facing each other with a corresponding light control pattern among the plurality of light control patterns interposed therebetween, and spaced apart from each other by a first distance in a second direction perpendicular to the first direction; and
second side walls extending in the second direction and spaced apart from each other by a second distance which is greater than the first distance in the first direction with the corresponding light control pattern interposed therebetween,
wherein each of the first side walls includes a first inclined surface inclined in a direction away from the corresponding light control pattern.

2. The display device of claim 1, wherein the first side walls include a (1-1)^{th} side wall and a (1-2)^{th} side wall facing each other with the corresponding light control pattern interposed therebetween.

3. The display device of claim 2, wherein the first inclined surface includes:
a (1-1)^{th} inclined surface formed on the (1-1)^{th} side wall; and
a (1-2)^{th} inclined surface formed on the (1-2)^{th} side wall.

4. The display device of claim 3, wherein a first width of the (1-1)^{th} inclined surface in the second direction is the same as a second width of the (1-2)^{th} inclined surface in the second direction.

5. The display device of claim 4, wherein each of the first width and the second width is in a range of about 3.5 micrometers or more and about 4.0 micrometers less.

6. The display device of claim 1, wherein the second side walls include a (2-1)^{th} side wall and a (2-2)^{th} side wall facing each other with the corresponding light control pattern interposed therebetween.

7. The display device of claim 6, wherein at least some of the second side walls include a second inclined surface inclined in the direction away from the corresponding light control pattern, and
the second inclined surface includes:
a (2-1)^{th} inclined surface formed on the (2-1)^{th} side wall; and
a (2-2)^{th} inclined surface formed on the (2-2)^{th} side wall.

8. The display device of claim 1, wherein each of the first side walls further includes a first side surface extending from the first inclined surface and being in direct contact with the plurality of light control patterns.

9. The display device of claim 8, wherein each of the plurality of openings includes:
a first sub-opening defined by the first inclined surface; and
a second sub-opening defined by the first side surface.

10. The display device of claim 9, wherein a width of the first sub-opening in the second direction gradually decreases toward the second sub-opening.

11. The display device of claim 10, wherein a maximum width of the first sub-opening in the second direction is in a range of about 34.8 micrometers or more and about 35.8 micrometers or less.

12. The display device of claim 9, wherein a width of the second sub-opening in the second direction gradually increases as a distance from the first sub-opening increases.

13. The display device of claim 1, wherein the plurality of light control patterns includes first control pattern to third light control pattern arranged in the first direction, and
the plurality of side walls further includes a non-inclined side wall in contact with the third light control pattern.

14. The display device of claim 13, wherein the division pattern is provided in plural, and
a width between two adjacent division patterns among a plurality of division patterns in the second direction is in a range of about 13 micrometers or more and about 15 micrometers or less.

15. The display device of claim 1, wherein the first inclined surface has non-liquid repellent properties.

16. A method of manufacturing a display device, the method comprising:
arranging a base member;
arranging a preliminary division pattern on the base member;
forming, on the preliminary division pattern, first side walls extending in a first direction and spaced apart from each other by a first distance in a second direction perpendicular to the first direction and second side walls extending in the second direction and spaced apart from each other by a second distance which is greater than the first distance in the first direction;
forming a first inclined surface by patterning upper portions of the first side walls;
providing an ink composition to an opening defined by the first side walls and the second side walls; and
forming a light control layer including a light control pattern by curing the ink composition,
wherein in the providing the ink composition, the ink composition is provided to overlap the first inclined surface.

17. The method of claim 16, wherein the forming the first inclined surface is performed simultaneously with the forming the first side walls.

18. The method of claim 16, wherein the first inclined surface is formed in a direction away from the light control pattern.

19. The method of claim 16, wherein the base member includes a base substrate and a color filter layer disposed on the base substrate, and
the preliminary division pattern is formed on one surface of the color filter layer.

20. The method of claim 19, further comprising:
providing a display panel including a display element layer; and
assembling the light control layer and the display panel.
